(19) United States
(12) Patent Application Publication
(10) Pub. No.: US 2020/0143095 A1
(43) Pub. Date: May 7, 2020

(54) DETERMINATION OF COMPATIBLE EQUIPMENT IN A MANUFACTURING ENVIRONMENT

(71) Applicant: Hewlett-Packard Development Company, L.P., Spring, TX (US)

(72) Inventors: Sunil Kothari, Palo Alto, CA (US); Thomas J Peck, Corvallis, OR (US); Jun Zeng, Palo Alto, CA (US); Gene Allen McDaniel, JR., Palo Alto, CA (US); Gary J. Dispoto, Palo Alto, CA (US)

(73) Assignee: Hewlett-Packard Development Company, L.P., Spring, TX (US)

(21) Appl. No.: 16/737,463

(22) Filed: Jan. 8, 2020

Related U.S. Application Data
(63) Continuation of application No. 15/307,729, filed on Oct. 28, 2016.

(51) Int. Cl. G06F 30/20; G05B 19/418

(52) U.S. Cl. CPC G06F 30/20; Y02P 90/26; G05B 2219/32366; G05B 19/41885

(57) ABSTRACT

Determining compatible equipment in a manufacturing environment is disclosed. A method includes developing a list of compatible equipment for a manufacturing line to produce a product based on process information related to the product. The list of compatible equipment and a manufacturer constraint are modeled. Modeling includes at least one of developing manufacturing line scenarios, simulating the manufacturing line scenarios, and weighing the simulations against production metrics.

### BACKGROUND

A manufacturing environment includes a manufacturing line to create a product for a customer. A manufacturing line typically includes a group of machines that are configured to receive an input, make transformations, and create a product via a selected manufacturing process. In some instances, a machine in the manufacturing line can be configured to create several products through changes in the manufacturing process, changes in machine configurations, changes in inputs, or a combination of these changes.

### BRIEF DESCRIPTION OF THE DRAWINGS

FIG. 1 is a directed graph illustrating an example workflow of an example manufacturing process that can be subjected to the example processes and systems of the disclosure.

FIG. 2 is a block diagram illustrating an example process for determining equipment compatible with a selected manufacturing process in a manufacturing environment, such as the manufacturing process of FIG. 1.

FIG. 3 is a flow diagram illustrating an example process used in the example process for determining compatible equipment of FIG. 2.

FIG. 4 is a flow diagram illustrating an example process used in the example process for determining compatible equipment of FIG. 2.

FIG. 5 is a block diagram illustrating an example computing device for use with an example system to perform the example processes of FIGS. 2-4.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

The example processes and systems in this disclosure are described in the context of industrial printing, but the disclosed processes and systems are applicable to other manufacturing domains including three dimensional printing, steel manufacturing, the automobile industry, and any other domain where a set of machines is configured and analyzed for capacity or capability matches or mismatches. The terms machine and equipment are used interchangeably.

An automated process to determine compatible equipment in a manufacturing environment is disclosed. This automated process can include a method, a computer readable medium including instructions for performing the method, and a system to develop a list of compatible equipment for a manufacturing line to produce a product based on process information related to the product. The list of compatible equipment and a manufacturer constraint are modeled, which includes at least one of developing manufacturing line scenarios, simulating the manufacturing line scenarios, and weighing the simulations against production metrics.

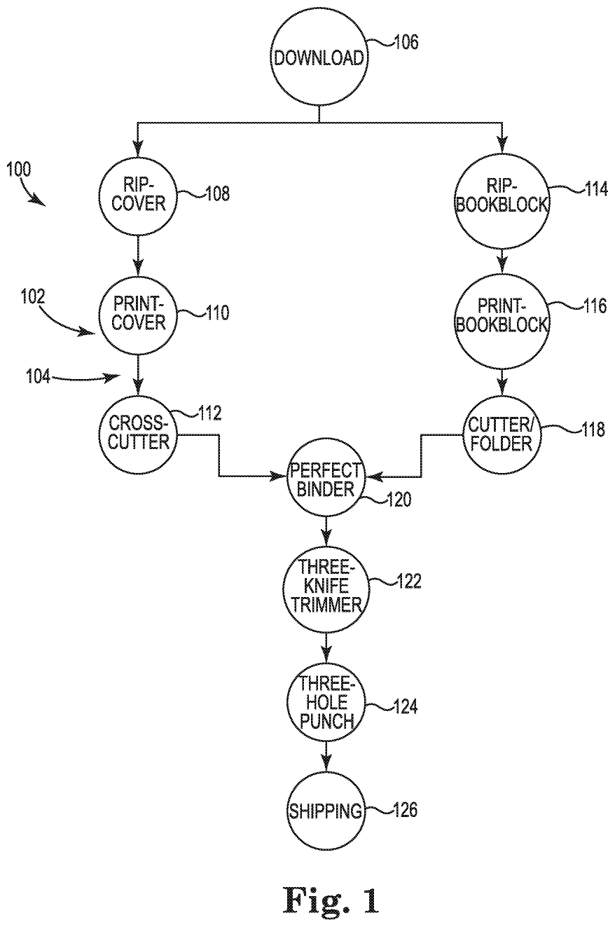

FIG. 1 illustrates an example workflow 100 of an example manufacturing process that is referred to below to exemplify the determination of compatible equipment in the automated process. The manufacturing process is used to create a product that is part of a customer's order. In this example, the workflow 100 includes a set of tasks to be performed. For instance, the product is created from a set of dependent tasks as described in a production plan and depicted in the workflow 100. In the example, the dependent tasks are configured in a directed graph. The tasks are represented as nodes 102 and the dependencies are represented as the edges 104 of the graph. The tasks in the workflow 100 can be assigned to a corresponding resource, such as a particular piece of equipment or to one or more machines selected from a set of suitable equipment.

The example workflow 100 depicts a manufacturing process to create bound booklets. The workflow 100 is depicted in the form of a directed acyclic graph, or DAG. In cases of a process including a re-work procedure, re-entry edges can be appended on the DAG resulting in a directed cyclic graph. Depending on different modes and production situations, a failed job at one process can be routed to different upstream processes for re-work. Other examples are contemplated.

The example workflow 100 begins at a download 106, where information is provided to the machines, which are prepared to run with materials to create the bound booklets. The workflow 100 separates into two tracks, which can be performed concurrently, that will produce a cover and a book block. In the example, the track of the cover includes raster image processing the cover 108, printing the cover 110, and cross trimming the cover 112. Also in the example, the track of the book block includes raster image processing the book block 114, printing the book block 116, and trimming/folding the book block 118. The book block and cover are bound together 120, trimmed 122 such as with a three-knife trimmer, and hole punched 124 to create the bound booklet. The bound booklet is then prepared for shipping 126.

The equipment selected to produce the product can be determined based on the customer's order. In some cases, the number of booklets to be produced or the types of materials to be used to create the booklet affect the choice of equipment. In many instances, the end-to-end process of manufacturing the product drives the type of equipment used to perform a task. For example, a manufacturer expecting to increase capacity might consider appropriate upgrades to the entire manufacturing line rather than just a piecemeal upgrade to a larger printing press. When upgrading, a manufacturer is likely to consider issues such as whether a faster printing press might help with one customer but otherwise create excess capacity and whether to use the excess capacity to make larger books in short runs of manufacturing or smaller books in long runs of manufacturing. Thus, upgrading a printing press may involve other considerations such as the capabilities of the manufacturer's finishing equipment, for example.

An inefficient, incorrect, or mismatched group of equipment on the manufacturing line can create undesirable results. Such undesirable results can include a poor quality product, low throughput, increased cycle times, and a low return on investment. In extreme cases, the equipment can go unused. The room for error in matching equipment capability to customer orders or expected orders is often small as many pieces of equipment are expensive to purchase and implement and thus greatly affect a manufacturer's net income or net earnings.

Currently, manufacturers use a static and manual process to determine the equipment for a manufacturing line upgrade. Often, upgrading is based on spreadsheets depicting system architecture and on the suggestions of floor managers, and such information and recommendation does not appropriately capture the dynamics of manufacturing. Quantities such as throughput, cycle time, and return on investment are not appropriately depicted in static analysis or educated guesses of manufacturing personnel.

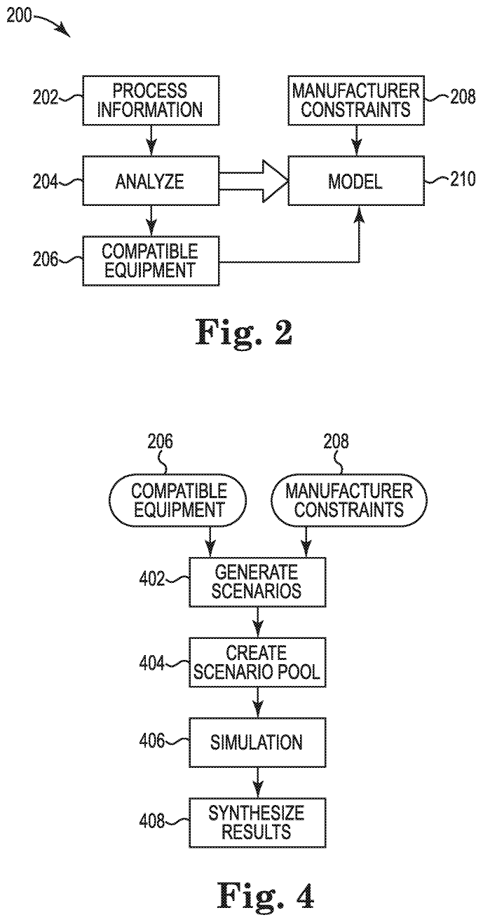

FIG. 2 illustrates a process 200 to determine equipment compatibility in a workflow. Process 200 receives process information 202 for each selected product to be manufactured. In one example, the process information can be retrieved from a database or other storage. The process information 202 includes the workflows for each product, information regarding the materials to be used to make the product, the equipment specifications for the equipment available to upgrade or otherwise change the manufacturing line, and the settings for the equipment available to upgrade the manufacturing line. The process information 202 can include specifications and settings for the equipment currently used in the manufacturing line. This information is analyzed 204, such as with an analyzer tool and computing device, to develop a list of compatible equipment 206 that have a capability to perform a task in the manufacturing process and are compatible with other equipment performing other tasks in the manufacturing process. In one example, equipment that is not capable of performing the selected manufacturing tasks or are otherwise incompatible with other equipment that can perform other tasks of the manufacturing process are filtered and not included in the list of compatible equipment 206. For example, a task such as printing a book block 116 may develop a list of several printing presses that are compatible with several other pieces of finishing equipment that can be used in downstream manufacturing nodes.

The list of compatible equipment 206 and one or more manufacturer constraints 208 are collected for modeling 210. The list of compatible equipment 206 and the one or more manufacturer constraints 208 can be retrieved from a storage. Examples of manufacturer constraints 208 can include budget information such as maximum price, or physical constraints such as factory size, required power to operate the manufacturing line, amount of workers to operate the manufacturing line, or additional goals of the manufacturer such as “on-time delivery of at least 95%.” Further, an optimal combination of compatible equipment for one manufacturer may not be optimal for another manufacturer if it does not include the factory space for the equipment or the available funds to purchase the equipment.

The modeling 210 is applied to determine dynamic behavior of the various combinations of equipment associated with the tasks. Modeling 210 can be performed with a modeling tool. The modeling configures different permutations of the manufacturing line and scenarios from the list of compatible equipment 206 with the manufacturing constraints 208 taken into context and simulates production runs. The simulations can be performed with a simulation engine. The scenarios corresponding with the simulated runs are weighed against various production metrics such as return on investment, equipment utilization, throughput, cycle time to determine preferred configurations of equipment in the manufacturing line. For example, the scenarios corresponding with the simulated runs can be ranked in order of the production metrics and can be used to determine a plan to upgrade the manufacturing line. The production metrics can be retrieved from a storage and the rankings can be displayed or stored. In one example, however, the modeling includes at least one of developing manufacturing line scenarios, simulating the manufacturing line scenarios, and weighing the simulations against the production metrics.

As used in this disclosure, each piece of equipment has a set of capabilities. A machine can have one or more operating modes based on inputs or operating policies, and a machine can have different settings that correspond with the different modes. For example, a single printing press may be set to produce a mono-color or four-color images. Each machine can include one or more inputs and one or more outputs. In one example, the inputs to one machine might include outputs from another machine as well as materials, or consumables, such as substrates or ink. Inputs and outputs are modeled as an attribute value pair, and each attribute corresponds with a particular piece of equipment.

The inputs and outputs have relationships that can be specified with expressions referred to as product specific transformations and equipment specific transformations. For example, a particular transformation of a product is used to validate whether a given piece of equipment can produce the product. In one example, product specific transformations return integer or decimal values. Product specific transformations are per product and map how an input, such as incoming materials like substrates, is transformed as it passes through the line. In one example, the product specific transformation captures the functionality of the equipment. Equipment specific constraints can be used to validate the product specific transformations. Equipment specific constraints are comparisons, such as Boolean expressions, that relate whether equipment has enough capability for an input. For example, a printing press that can accommodate a maximum of 60-inch width roll will not accept a 72-inch roll. (In some examples, a set of equipment less than the entire set of equipment in a manufacturing line can be represented as an equipment specific transformation. The illustrated example, however, contemplate that each piece of equipment is available for upgrade or change.) A set of equipment specific constraints typically remains the same for each product produced with the corresponding machine.

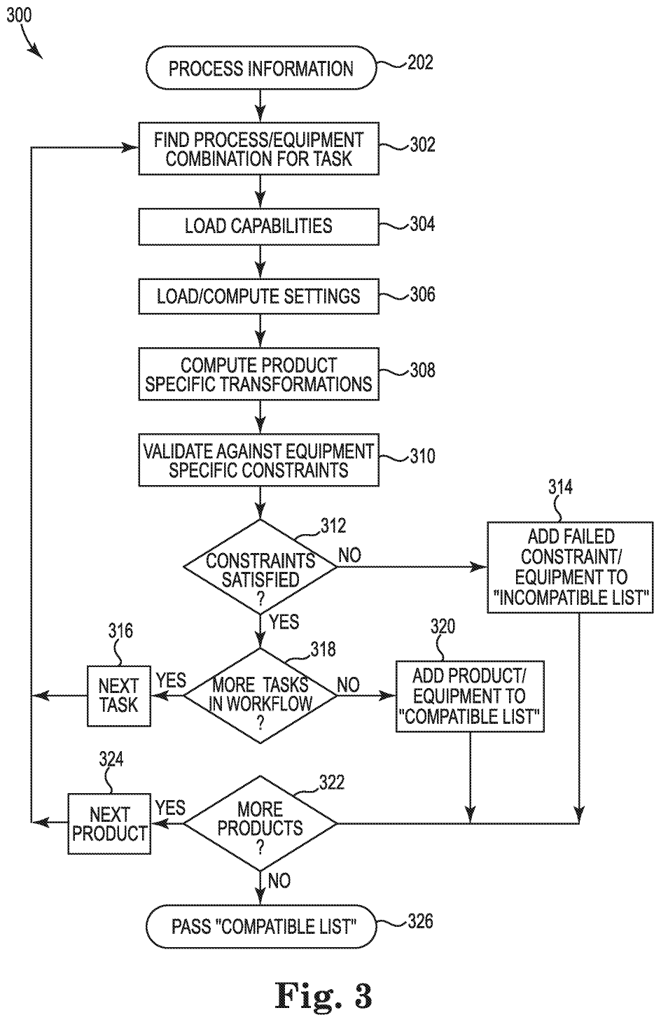

FIG. 3 illustrates an example analyzing process 300 that can be employed to perform the analyzing 204. Analyzing process 300 receives the process information 202 including the workflows for each product, information regarding the materials to be used to make the product, the equipment specifications for the equipment available to upgrade the manufacturing line, and the settings for the equipment available to upgrade the manufacturing line. Analyzing process 300 can output the list of compatible equipment 206.

The example analyzing process 300 considers the particular products that can be created with a piece of equipment. Each workflow, such as workflow 100 is considered for each product to be created. Each piece of equipment can be used to create several products. In this example, several combinations of products and workflows (product/workflow combination) are possible and several combinations of products, workflows, and equipment (product/workflow/equipment combination) are possible.

For each product/workflow combination, the analyzing process 300 includes finding a piece of equipment corresponding with the task at 302. The capabilities of the equipment are loaded at 304, and settings can be loaded and computed at 306. In one example, the capabilities provide the vocabulary for the settings. Product specific transformations are computed at 308 based on settings at 304 and attribute values at 304. The product specific transformations and equipment specific constraints are used to determine whether the given equipment or line at the task is capable of producing the product at 310. If the equipment specific constraints are not satisfied at 312, the failed constraint and equipment combination is filtered. In one example, the failed constraint and equipment combination is added to an ‘incompatible equipment’ list at 314 that can be subtracted from the list of available equipment prior to generating a compatible equipment list 206. In response to an unsatisfied constraint at 312, analyzing process begins investigating another product if another product remains at 322.

If, however, the constraints are satisfied at 312, the next task in the workflow at 316 is applied to process elements at 302 to 312 until all the tasks in the workflow have been investigated at 318. The particular equipment and product combination satisfying the constraints can be added to the ‘compatible equipment’ list 206 at 320.

The process elements at 302 to 320 can be repeated for each additional product/workflow combination for another product to be investigated at 324. Once all of the products/workflow/equipment combinations have been investigated at 322, the list of the ‘compatible equipment’ collected at 320, is passed at 326 to modeling 210.

FIG. 4 illustrates an example modeling process 400 for performing the modeling 210 with the list of compatible equipment 206 and the business constraints 208. The modeling process 400 creates a set of different manufacturing lines, or scenarios, at 402 with the compatible equipment 206. For example, if a manufacturing line included a printer and a finisher, and the list of compatible equipment included five different printers and five different finishers, the set of manufacturing lines created at 402 is twenty-five different scenarios. If sufficient information is known from the manufacturing constraints, additional scenarios can be created at 404 by adding additional pieces of equipment to the set of scenarios at 402 to generate a scenario pool. The scenarios in the scenario pool are simulated at 406 to quantify operation of the each of the manufacturing lines. In one example, the scenarios are simulated concurrently with a simulation engine. The information developed in the simulations at 406 can be consolidated in various categories such return on investment, equipment utilization, throughput, cycle time, and others. The scenarios can be ranked in order of these various categories to develop a recommended equipment list at 408 for a manufacturing line based on the manufacturer's business objectives.

A simulation engine can be employed to perform the simulation at 406. Example simulation engines can be employed at 406 include one or more products available from the Ptolemy Project from the University of California at Berkeley, from Simio LLC, of Sewickley, Pa., from The AnyLogic Company of St. Petersburg, Russian Federation, or others. Further, processes or simulations can be performed offline, sequentially, and otherwise with a computing device. For the sake of illustration, the examples below are generally set out in a Ptolemy II syntax.

In the example, capabilities of a machine are expressed as attribute values determined by the equipment manufacturer and the specific product designation. For example, capabilities can include such information as the maximum or minimum width of a web the machine can process, or the maximum or minimum weight of the media that can be printed, the maximum or minimum throughput, or the corresponding mode information, if any. For example, a digital printing press XYZ can have the capabilities:
{brand=“XYZ”, attr=“web_width_min”, mode=“none”, value=0*inch}, [symbol]
{brand=“XYZ”, attr=“web_width_max”, mode=“none”, value=34*inch}, [symbol]
{brand=“XYZ”, attr=“coated_media_weight_min”, mode=“none”, value=55*gsm},
{brand=“XYZ”, attr=“coated_media_weight_max”, mode=“none”, value=130*gsm},
{brand=“XYZ”, attr=“uncoated_media_weight_min”, mode=“none”, value=40*gsm},
{brand=“XYZ”, attr=“uncoated_media_weight_max”, mode=“none”, value=130*gsm},
{brand=“XYZ”, attr=“feederdrawer1”, mode=“none”, value=1800*A4sheets}

Equipment can have a set of inputs and a set of outputs with respect to a particular product/workflow combination. In the case where an input of a machine is an output from another piece of equipment, the input attributes and values can be accessed from a look up table or from a global data structure. In the case where the input of the machine is a material or consumable, the input attributes and values can be obtained from a storage such as a global database or a file system. An example syntax includes:
inputs={num=2, input0={nanne=“CoverSheets”, index=“input0”, ptr=“substrates”, process=“none”, resource=“A3_Sheets”, ref=“none”},
   input1={name=“RippedCover”, index=“input1”, ptr=“processCapabilities”, process=“RIP_Cover”, resource=“Harlequin1”, ref=“output0” [symbol]
outputs={num=1, output0={nanne=“PrintedRippedCover”, ptr=“none”, id=“none”}}

Additionally, a machine may have different modes of operation based on items including inputs or pre-selected operating policies. The capabilities of the machine can depend on the mode of operation. For example, the XYZ digital printing press above has a throughput dependent on the modes of “color,” “economy,” or “mono.”
{brand=“XYZ”, attr=“throughput_max”, mode=“color”, value=120*A4sheets/min},
{brand=“XYZ”, attr=“throughput_min”, mode=“economy”, value=0*A4sheets/min},
{brand=“XYZ”, attr=“throughput_max”, mode=“economy”, value=160*A4sheets/min},
{brand=“XYZ”, attr=“throughput_min”, mode=“mono”, value=0*A4sheets/min},
{brand=“XYZ”, attr=“throughput_max”, mode=“mono”, value=240*A4sheets/min},

Operational policies such as batching parameters can be specified in the settings section. Equipment can have different settings based on different products. Therefore, the product qualifies each setting. The following statement sets the speed of an inkjet web printing press ABC based on the substrate:
(Book) ABC_input0_media_coated==False=>ABC_production_speed=300 foot/min
(PhotoBook) ABC_input0_media_coated==True=>ABC_production_speed=200 foot/min

The inputs and outputs of a machine have relationships referred to as product specific transformations. For example, the input to a bookbinder is a cover and a book block. The output from a thermally activated perfect binder (where ‘perfect binding’ is a term of art that refers to a form of thermal activated binding) can be a book with cover glued to the book block. The product specific transformations describe how physical attributes such as height, width and thickness of the cover and book block are transformed for a given perfect bound book. For example, product specific transformations for a perfect binder DEF can include:
DEF_output0_length=max (DEF_input0_length, DEF_input1_length), where input0 refers to the cover and input1 refers to the bookblock.
DEF_output0_thickness=2*DEF_input0_thickness+DEF_input1_thickness where input0 refers to the cover and input1 refers to the bookblock.

In one example, Equipment Specific Constraints are configured as Boolean expressions. For example, a binder QRS includes cover and block size limits for producing booklets:
QRS1_cover_height_min<QRS1_input0_height<QRS1_cover_height_max; QRS1_cover_width_min<
QRS1_input0_width<QRS1_cover_width_max; QRS1_bookblock_height_min<QRS1_input0_height<
QRS1_bookblock_height_max; QRS1_bookblock_width_min<QRS1_input1_width<
QRS1_bookblock_width_max; QRS1_bookblock_thickness_min<QRS1_input1_thickness<QRS1_bookblock_thickness_max

These relationships may be guarded based on the mode of the equipment. For example, if the three-knife trimmer is in the straight mode then different constraints are used when to operating in left or right mode. For example:
1) mode==‘straight’=> [symbol] QRS2_in_trim_thickness_min<QRS2_input0_thicknes<QRS2_in_trim_thickness_max
2) mode==‘straight’=> [symbol] QRS2_in_trim_height_min<QRS2_input0_height<QRS2_in_trim_height_max
3) mode==‘straight’=>QRS2_in_trim_width_min<QRS2_input0_width<QRS2_in_trim_width_max

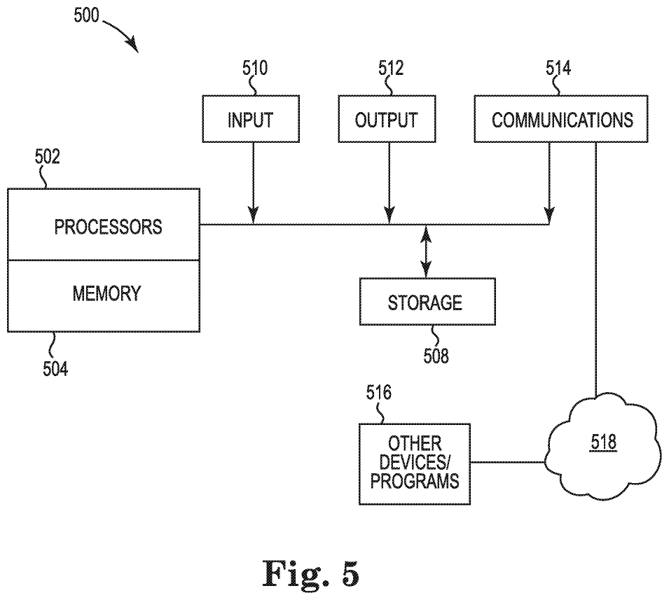

FIG. 5 illustrates an example computer system that can be employed in an operating environment and used to host or run a computer application included on one or more computer readable storage mediums storing computer executable instructions for controlling the computer system, such as a computing device, to perform a process. In one example, the computer system of FIG. 5 can be used to implement the process to determine compatible equipment in a manufacturing environment, such as process 200, its associated processes 300 and 400, and a simulation engine. Process 300 can be performed with analyzer tool operating on the computing device, and process 400 can be performed with a modeling tool operating on a computing device. In one example, process 200 is performed in a distributed computing system including the computing device.

The exemplary computer system of FIG. 5 includes a computing device, such as computing device 500. Computing device 500 typically includes one or more processors 502 and memory 504. The processors 502 may include two or more processing cores on a chip or two or more processor chips. In some examples, the computing device 500 can also have one or more additional processing or specialized processors (not shown), such as a graphics processor for general-purpose computing on graphics processor units, to perform processing functions offloaded from the processor 502. Memory 504 may be arranged in a hierarchy and may include one or more levels of cache. Memory 504 may be volatile (such as random access memory (RAM)), nonvolatile (such as read only memory (ROM), flash memory, etc.), or some combination of the two. The computing device 500 can take one or more of several forms. Such forms include a tablet, a personal computer, a workstation, a server, a handheld device, a consumer electronic device (such as a video game console or a digital video recorder), or other, and can be a stand-alone device or configured as part of a computer network, computer cluster, cloud services infrastructure, or other.

Computing device 500 may also include additional storage 508. Storage 508 may be removable and/or non-removable and can include magnetic or optical disks or solid-state memory, or flash storage devices. Computer storage media includes volatile and nonvolatile, removable and non-removable media implemented in any suitable method or technology for storage of information such as computer readable instructions, data structures, program modules or other data. A propagating signal by itself does not qualify as storage media.

Computing device 500 often includes one or more input and/or output connections, such as USB connections, display ports, proprietary connections, and others to connect to various devices to receive and/or provide inputs and outputs. Input devices 510 may include devices such as keyboard, pointing device (e.g., mouse), pen, voice input device, touch input device, or other. Output devices 512 may include devices such as a display, speakers, printer, or the like. Computing device 500 often includes one or more communication connections 514 that allow computing device 500 to communicate with other computers/applications 516. Example communication connections can include, but are not limited to, an Ethernet interface, a wireless interface, a bus interface, a storage area network interface, a proprietary interface. The communication connections can be used to couple the computing device 500 to a computer network 518, which is a collection of computing devices and possibly other devices interconnected by communications channels that facilitate communications and allows sharing of resources and information among interconnected devices. Examples of computer networks include a local area network, a wide area network, the Internet, or other network.

Computing device 500 can be configured to run an operating system software program and one or more computer applications, which make up a system platform. A computer application configured to execute on the computing device 500 is typically provided as set of instructions written in a programming language. A computer application configured to execute on the computing device 500 includes at least one computing process (or computing task), which is an executing program. Each computing process provides the computing resources to execute the program.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A method of determining compatible equipment in a manufacturing environment, comprising:
determining that equipment is capable of performing tasks in a manufacturing process;
determining that the equipment is compatible with other equipment performing other tasks in the manufacturing process;
developing a list of compatible equipment for a manufacturing line to produce a product based on process information related to the product, the determination that equipment is capable of performing tasks in the manufacturing process and the determination that the equipment is compatible with other equipment performing other tasks in the manufacturing process; and
modeling the list of compatible equipment and a manufacturer constraint wherein the modeling includes at least one of developing manufacturing line scenarios, simulating the manufacturing line scenarios, and weighing the simulations against production metrics.

2. The method of claim 1 wherein the process information includes workflows for each product, information regarding the materials to make each product, equipment specifications for available equipment, and settings for the available equipment available.

3. The method of claim 1 wherein the manufacturing constraints include budget information and factory size information.

4. The method of claim 1 wherein the production metrics include return on investment, equipment utilization, manufacturing throughput, and cycle time.

5. The method of claim 1 comprising ranking the scenarios with respect to the production metrics.

6. The method of claim 1 wherein the developing includes evaluating whether a particular combination of product, equipment, and manufacturing process are compatible.

7. The method of claim 1 wherein the developing includes developing attributes and capabilities of a combination of a task in a workflow and equipment to perform the task into a product specific transformation.

8. The method of claim 7 wherein an invalidation of a product specific transformation develops an incompatible combination of task and equipment.

9. The method of claim 8 wherein the equipment in the incompatible combination of task and equipment is not included in the list of compatible equipment.

10. The method of claim 1 wherein the modeling includes developing manufacturing line scenarios, simulating the manufacturing line scenarios, and weighing the simulations against production metrics.

11. A computer readable medium for storing computer executable instructions for controlling a computing device to perform a method of determining compatible equipment in a manufacturing environment, the method comprising:
determining that equipment is capable of performing tasks in a manufacturing process;
determining that the equipment is compatible with other equipment performing other tasks in the manufacturing process;
developing a list of compatible equipment for a manufacturing line to produce a product based on process information related to the product, the determination that equipment is capable of performing tasks in the manufacturing process and the determination that the equipment is compatible with other equipment performing other tasks in the manufacturing process; and
modeling the list of compatible equipment and a manufacturer constraint wherein the modeling includes at least one of developing manufacturing line scenarios, simulating the manufacturing line scenarios, and weighing the simulations against production metrics.

12. The computer readable medium of claim 11 wherein the process information is retrieved from a storage.

13. The computer readable medium of claim 11 wherein the developing includes developing attributes and capabilities of a combination of a task in a workflow and equipment to perform the task into a product specific transformation.

14. A system for determining compatible equipment in a manufacturing environment, comprising:
an analyzer to:
determine that equipment is capable of performing tasks in a manufacturing process;
determine that the equipment is compatible with other equipment performing other tasks in the manufacturing process; and
develop a list of compatible equipment for a manufacturing line to produce a product based on process information related to the product, the determination that equipment is capable of performing tasks in the manufacturing process and the determination that the equipment is compatible with other equipment performing other tasks in the manufacturing process; and
a modeler to model the list of compatible equipment and a manufacturer constraint wherein modeling includes at least one of developing manufacturing line scenarios, simulating the manufacturing line scenarios, and weighing the simulations against production metrics.

15. The system of claim 14 wherein the modeler includes a simulation engine operating on a computing device.

16. The method of claim 1 wherein a processor determines that equipment is capable of performing tasks in a manufacturing process and determines that the equipment is compatible with other equipment performing other tasks in the manufacturing process.

17. The method of claim 1 wherein developing the list of compatible equipment comprises:
retrieving the process information from a storage;
finding equipment corresponding with a task in the manufacturing process based on the process information;
loading capabilities and settings of the equipment;
computing a product specific transformation based on the capabilities and settings of the equipment; and
determining whether the equipment is capable of producing the product based on the product specific transformation and equipment specific constraints.
